(19) United States
(12) Patent Application Publication
(10) Pub. No.: US 2025/0226308 A1
(43) Pub. Date: Jul. 10, 2025

(54) SEMICONDUCTOR DEVICE WITH BACKSIDE CONNECTION MECHANISM AND METHODS FOR MANUFACTURING THE SAME

(71) Applicant: Micron Technology, Inc., Boise, ID (US)

(72) Inventors: Bharat Bhushan, Taichung (TW); Brent Keeth, Boise, ID (US); Kunal R. Parekh, Boise, ID (US); Akshay N. Singh, Boise, ID (US)

(21) Appl. No.: 18/936,552

(22) Filed: Nov. 4, 2024

Related U.S. Application Data
(60) Provisional application No. 63/618,780, filed on Jan. 8, 2024.

(51) Int. Cl. H01L 23/522; H01L 21/768; H01L 23/00; H01L 23/528; H01L 25/065

(52) U.S. Cl. CPC H01L 23/5226; H01L 21/76807; H01L 23/528; H01L 24/08; H01L 25/0657; H01L 2224/08145; H01L 2225/06541; H01L 2924/1436

(57) ABSTRACT

Methods, apparatuses, and systems related to a memory device having on its backside one or more integrally-formed structures is described. A memory device may include a backside pad-via structure, a backside redistribution layer structure, or a combination thereof. Such backside structures may include integrally-formed portions that extend in different directions to laterally route electrical signals on the backside.

### CROSS-REFERENCE TO RELATED APPLICATION(S)

The present application claims priority to U.S. Provisional Patent Application No. 63/618,780, filed Jan. 8, 2024, the disclosure of which is incorporated herein by reference in its entirety.

### TECHNICAL FIELD

The disclosed embodiments relate to devices, and, in particular, to semiconductor devices with backside connection mechanism and methods for manufacturing the same.

### BACKGROUND

A semiconductor device can include one or more circuits, such as a combination of connected transistors, capacitors, and other similar circuit components, fabricated or embedded in semiconductor material. Some examples of the semiconductor device can include a semiconductor die, a package, a system-on-chip, a circuit card, or the like including the semiconductor-based circuits. Such semiconductor device can be configured for a variety of functions, as for a processor or a memory device (e.g., a volatile memory device, a non-volatile memory device, or a combination device).

With technological growth and increasing applications, the market is continuously looking for faster, more efficient, and smaller devices. To meet the market demand, the semiconductor devices are being pushed to the limit with various improvements. Improving devices, generally, may include increasing circuit density, reducing the circuit footprint, increasing operating speeds or otherwise reducing operational latency, increasing reliability, reducing power consumption, or reducing manufacturing costs, among other metrics. For example, three-dimensional (3D) architectures are being researched for semiconductor device designs.

### BRIEF DESCRIPTION OF THE DRAWINGS

FIG. 1 is a block diagram of an apparatus in accordance with an embodiment of the present technology.

FIG. 2A is a cross-sectional view of a first set of stacked devices having a first connection configuration.

FIG. 2B is a cross-sectional view of a second set of stacked devices having a second connection configuration.

FIG. 3A is a cross-sectional view of a first example device having a first backside (BS) connection mechanism in accordance with an embodiment of the present technology.

FIG. 3B is a cross-sectional view of the first example device connected to a stacked device in accordance with an embodiment of the present technology.

FIG. 3C is a waterfall diagram for a first stacked assembly in accordance with an embodiment of the present technology.

FIG. 4 is a plan view of a redistribution layer associated with the BS connection mechanism in accordance with an embodiment of the present technology.

FIG. 5A is a cross-sectional view of a second assembly having a second BS connection mechanism connected to a stacked device in accordance with an embodiment of the present technology.

FIG. 5B is a waterfall diagram for the second assembly in accordance with an embodiment of the present technology.

FIG. 6A is a cross-sectional view of a third assembly having a third BS connection mechanism connected to a stacked device in accordance with an embodiment of the present technology.

FIG. 6B is a waterfall diagram for the third assembly in accordance with an embodiment of the present technology.

FIGS. 7A-7J are illustrations of various stages of an example manufacturing process in accordance with an embodiment of the present technology.

FIG. 8 is a flow diagram illustrating an example method of manufacturing a semiconductor device with a BS routing mechanism in accordance with an embodiment of the present technology.

FIG. 9 is a schematic view of a system that includes a semiconductor device in accordance with an embodiment of the present technology.

### DETAILED DESCRIPTION

As described in greater detail below, the technology disclosed herein relates to a semiconductor device having a backside (BS) connection mechanism, such as for memory systems, systems with memory devices, etc., and related methods. The BS connection mechanism can include circuitry or signal routing structures located on a BS or an inactive side of a semiconductor device (e.g., a die, a wafer, or the like) and configured to route electrical connections or signals along one or more directions. Moreover, the BS connection mechanism can be configured to facilitate electrical coupling between wafer-bonded structures, such as along vertical directions between stacked/directly bonded wafers or corresponding dies.

In some embodiments, the BS routing mechanism can be formed using a dual damascene (DD) manufacturing process. Accordingly, the BS routing mechanism can have traits or structural features characteristic of DD structures, such as integral, continuous, or non-attached transitions between structure portions. For example, the BS routing mechanism can have the characteristics of laterally extending traces, pads, and/or vias that are seamlessly connected to each other as a result being formed by a single/continuous metallization or depositing step through the DD process.

The BS routing mechanism can provide lateral signal routing while maintaining or decreasing the overall device thickness. The BS routing mechanism can include one or more layers of laterally extending traces and vias (e.g., BS redistribution layer (RDL)) that together provide full three-dimensional (3D) routing of electrical connections across stacked devices. Moreover, with the RDL located on the BS of the device, the BS routing mechanism can be separated from the front side circuits across a thickness or a body of the semiconductor. Thus, the 3D routing can be implemented without affecting or adjusting the front side circuit layout. Such division of signal routing can further increase scalable paths for fine pitch connections. Additionally, the BS routing mechanism can provide an offset bond design and enable direct (e.g., copper-to-copper) bonding across stacked devices while reducing overall resistance and thickness for the 3D electrical connections.

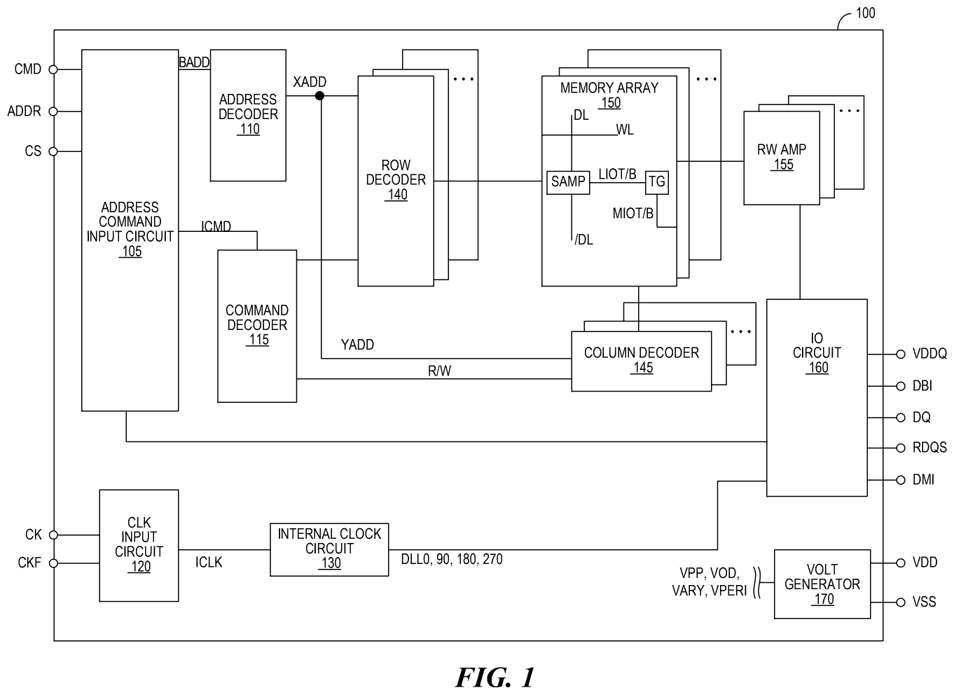

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0-15), and each bank may include a plurality of WLs, a plurality of DLs, and a plurality of memory cells arranged at intersections of the word-lines and the bit lines. Memory cells can include any one of a number of different memory media types, including capacitive, magnetoresistive, ferroelectric, phase change, or the like. Details regarding the structure of the WLs, the DLs, and the memory cells are described below.

The selection of a word-line WL may be performed by a row decoder 140, and the selection of a digit-line DL may be performed by a column decoder 145. Sense amplifiers (SAMP) may be provided for coupled digit-line DL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and related circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address (CA) input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials V_{DD} and V_{SS}. These power supply potentials V_{DD} and V_{SS} can be supplied to an internal voltage generator circuit 170. The internal voltage generator circuit 170 can generate various internal potentials V_{PP}, V_{OD}, V_{ARY}, V_{PERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DDQ}. The power supply potential V_{DDQ} can be supplied to the input/output circuit 160 together with the power supply potential V_{SS}. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to the internal clock circuit 130 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

The memory arrays 150 can be formed using one or more memory dies. These memory dies may be stacked physically in a vertical manner. These memory dies can be part of a memory stack on top of a logic (IF) die, a central processing unit (CPU) die, and/or a graphic processing unit (GPU) die. Within the stack, each memory die can be coupled to another memory die through interconnections. As the number of memory arrays 150 increases, so does the number of routings between them. Hence, increasing the memory arrays 150 may require similar increases in the interconnection structures within the dies/stack. In one embodiment, the interconnection structures can be achieved by an interconnection that includes a combination of a dual damascene (DD) redistribution layer (RDL) and DD via last (VL). In another embodiment, these can be achieved by a DD pad and a via. In another embodiment, these can be achieved by the combination of the above-mentioned embodiments.

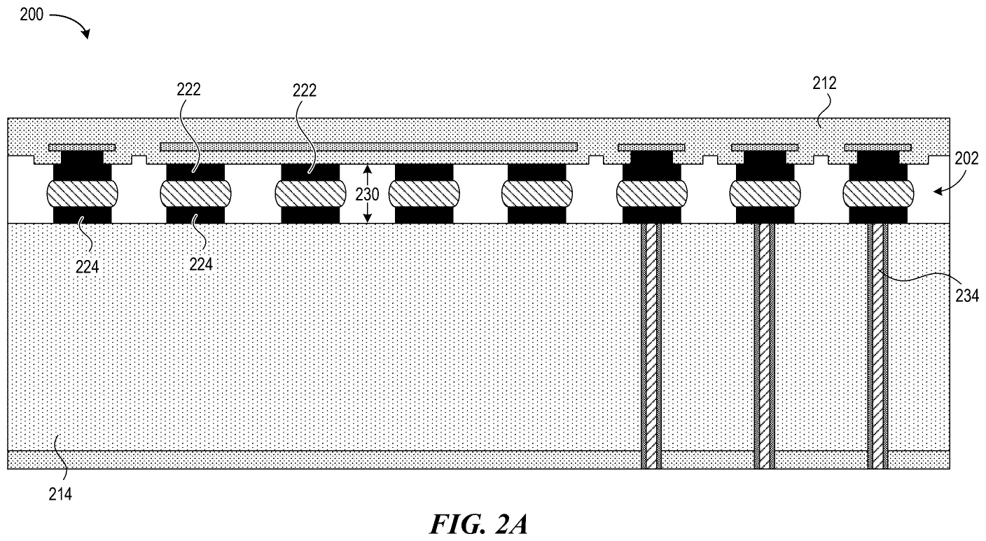

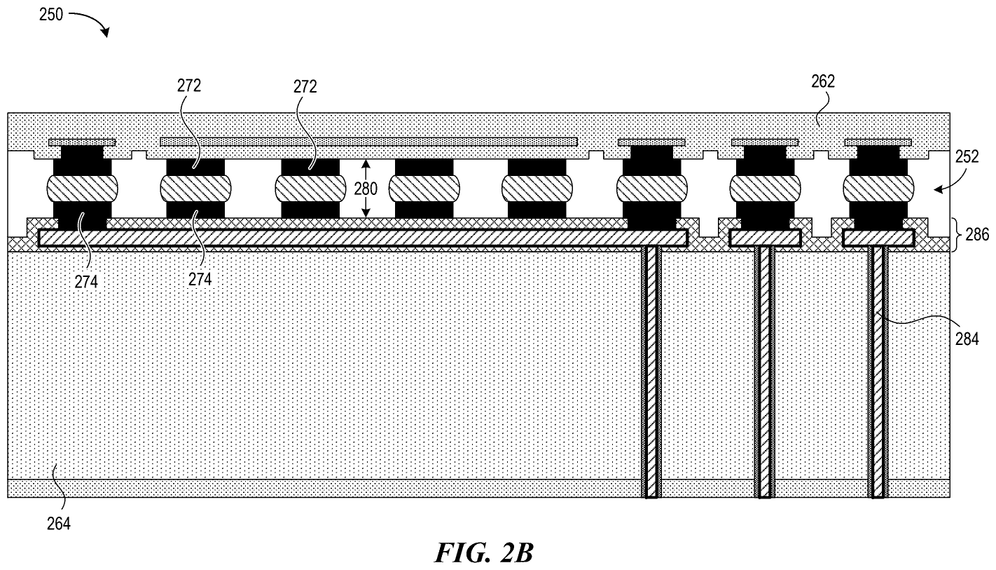

FIG. 2A is a cross-sectional view of a first set of stacked devices 200 having a first connection configuration. The first connection configuration can include a set of interconnects 202 (e.g., solder, micro bumps, conductive pillars, or the like) electrically and/or structurally connecting a top device 212 and a bottom device 214 (e.g., stacked semiconductor wafers or corresponding dies). The top device 212 can include a set of top-device pads 222 directly contacting/attached to the interconnects 202. The bottom device 214 can include a set of bottom-device pads 224 directly contacting/attached to the interconnects 202. Accordingly, the first set of stacked devices 200 can have a separation distance 230 between adjacent/facing surfaces of the top device 212 and the bottom device 214.

The first set of stacked devices 200 can include bottom-device vias 234 directly attached to the bottom-device pads 224. Moreover, the connecting region between the bottom-device vias 234 and the bottom-device pads 224 can have characteristics, such as layering, uneven or protruding edges, layers or uneven protrusions in the surrounding structures (e.g., dielectric), or the like associated with being formed or deposited in two separate processes. In addition to the connection characteristics, the bottom-device vias 234 can extend vertically or straight down.

While the first set of stacked devices 200 can vertically connect the top device 212 and the bottom device 214, the use of the interconnects 202 results in unnecessary increase in the separation distance 230. Moreover, the interconnects 202 and the resulting separation distance 230 fail to provide adequate structural support for the overall structure. For example, when implemented in wafer-to-wafer bonding, such that the top and bottom devices correspond to semiconductor wafers, the separation between the wafers prevent the two wafers from forming a single structure. As such, both wafers are each required to retain minimal thickness to prevent structure damage. Additionally or alternatively, one or more of the wafers would require temporarily bonded adhesive carrier system to preserve the structural integrity during and/or after the semiconductor manufacturing process.

Moreover, the direct connection between the bottom-device vias 234 and the bottom-device pads 224 force all lateral signal routing to occur on one side of the device, such as the active side of the bottom device 214. Accordingly, the active side becomes more crowded and unable to support the increasing demand for higher signal density. Moreover, the vias are required to extend over the thicker body of the bottom device. Along with the interconnects 202, the longer vias provide unnecessary resistance that require higher power levels and generate more heat.

FIG. 2B is a cross-sectional view of a second set of stacked devices 250 having a second connection configuration. The second connection configuration can include components similar to the first set of stacked devices 202 of FIG. 2A. For example, the second set of stacked devices 250 can include interconnects 252 connecting a top device 262 and a bottom device 264 (e.g., stacked semiconductor wafers or corresponding dies). Similar to the first set of stacked devices 202, the devices in the second set of stacked devices 250 can (1) include top-device pads 272 and bottom-device pads 274 directly attached to the interconnects 252 and (2) be separated by a separation distance 280. Further, the bottom device 264 can include bottom-device vias 284.

Different from the first set of stacked devices 200, the bottom device 264 can include a RDL 286 disposed between the bottom-device vias 284 and the bottom-device pads 274. The RDL 286 can include electrical connectors, such as leads, traces, local vias, connection planes, separating dielectric layers, or a combination thereof configured to route electrical signals/connections along lateral directions across one or more lateral layers.

The inclusion of the RDL 286 on the BS of the bottom device 264 can provide additional layers for lateral signal routing between devices, thereby alleviating the signal density of the front side. Accordingly, the second set of stacked devices 250 can have a finer pitch (e.g., 15-20 um) than the first set of stacked devices 200.

However, the second set of stacked devices 250 still requires additional structural support during manufacturing due to the use of the interconnects 252. Moreover, in attaching the devices with the interconnects 252, the manufacturing process requires separate temperature based processing steps, such as a higher temperature process for forming front-side (FS) solder on the top device 262 and a lower temperature process for BS under-bump metal (UBM) on the bottom device 264. Additionally, the RDL 286 can be formed using a semi-additive process, which may yield thicker RDL and passivation layers and thereby increase unwanted parasitic capacitance. Such RDLs can have larger feature sizes and pitches resulting in low density.

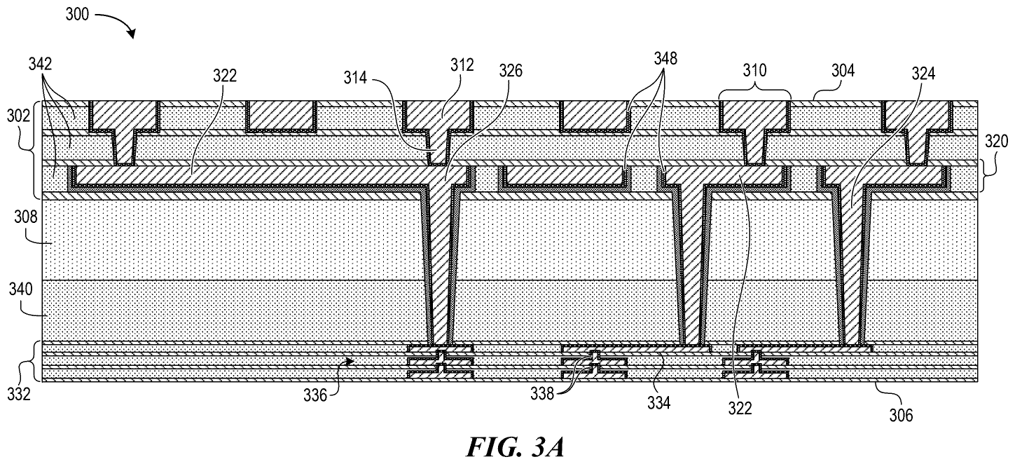

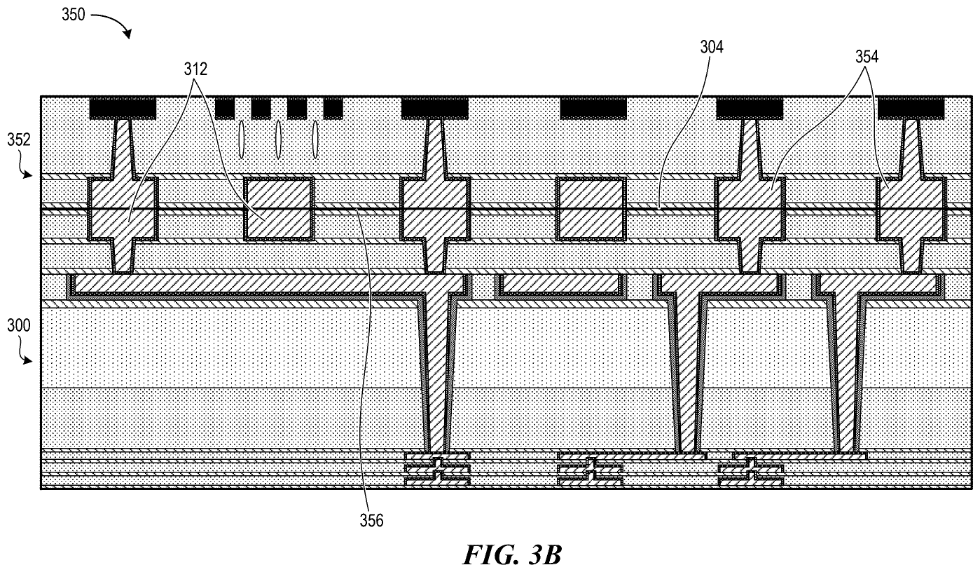

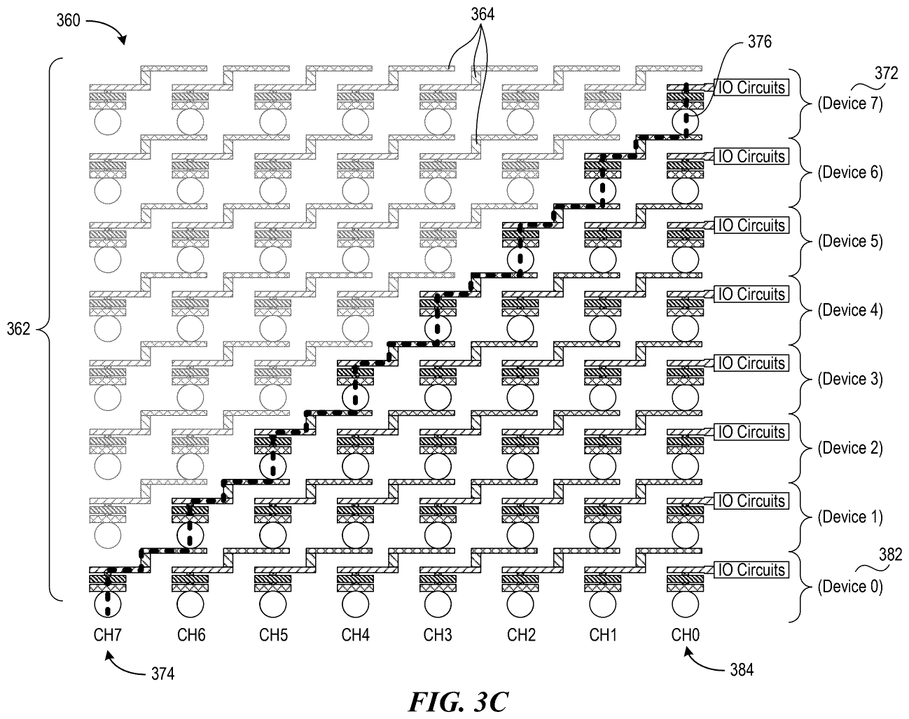

FIG. 3A is a cross-sectional view of a first example device 300 having a first BS connection mechanism 302 in accordance with an embodiment of the present technology. The device 300 can include a semiconductor wafer, and FIG. 3A can represent a portion of the wafer corresponding to one die (e.g., the apparatus 100 of FIG. 1, such as a DRAM). The device 300 can have a BS 304 and a frontside (FS) 306 surrounding or defining opposite sides of a core 308 (e.g., semiconductor substrate material, such as Silicon (Si)). The FS 306 can include active circuitry that implement functions, computations, and/or storage targeted for the device 300.

Unlike conventional designs, the device 300 can include the BS connection mechanism 302, which includes one or more layers that each have vertical and lateral portions integrally connected to each other. The integrally connected vertical and lateral connection portions can be formed using the DD process. Accordingly, the integrally connected portions can have one or more characteristics, such as rounded corners, integral joints, surrounding layer characteristics, or a combination thereof, that result from the DD manufacturing process.

As an illustration of the integrally joined portions, the BS connection mechanism 302 can include one or more DD pad-via structures 310 exposed on and/or defining an outer surface of the BS 304. The DD pad-via structures 310 can be configured to (1) provide an electrical connection and a direct structural bond with corresponding external structures (e.g., bond pads on a stacked/bonded wafer) while (2) while extending the electrical connection vertically (downward) to or through the next adjacent layer(s). Accordingly, the DD pad-via structures 310 can include electrical conductors that facilitate direct bonding, such as metallic material (e.g., Copper (Cu)). The conductive material of the DD pad-via structures 310 can have a pad portion 312 and a via portion 314 that are integral with each other. The pad portion 312 can be exposed on the peripheral surface to facilitate bonding, and the via portion 314 can extend vertically (e.g., down in FIG. 3A) from the pad portion 312 toward the core 308.

The pad portion 312 and the via portion 314 can have different shapes that correspond to their respective functions. For example, the pad portion 312 can have wider or longer lateral dimensions and a corresponding shape (e.g., rectangle or oval) than the via portion 314 to facilitate the device-to-device direct bond (e.g., Cu-to-Cu bond). Also, the via portion 314 can have greater depth or height than the pad portion 312 to facilitate the vertical electrical connection. Accordingly, while the shapes of the pad portion 312 and the via portion 314 define or form an integral joint 316, the material can be consistent, and the structure can be integral across the joint 316 as a result of forming the portions through one continuous deposition step (e.g., the DD manufacturing process). In other words, the DD pad-via structures 310 can have the integral joint 316 instead of junctions having structural divisions or consistency changes that result from being formed using multiple separate deposition steps (e.g., having other manufacturing steps between the separate depositions).

As a further illustration of the integrally joined portions, the BS connection mechanism 302 can additionally or alternatively include one or more BS DD RDL layers 320. The BS DD RDL layers 320 can be disposed between the pad portion 312 (e.g., outer surface of the BS 304) and the core 308. One or more of the BS DD RDL layers 320 can include one or more lateral portions 322 having electrically conductive material extending along lateral directions. The first device 300 can use the lateral portions 322 to communicate electrical signals, powers, ground connections, and the like laterally across a plane or a layer. One or more of the BS DD RDL layers 320 can further include one or more vertical portions 324 that include electrically conductive material extending along a vertical direction (e.g., downward). The vertical portions 324 can provide electrical connection vertically and across one or more layers, across a thickness of the core 308 (such as for TSVs), between active circuitry 340 (e.g., data storage circuits, such as transistors or capacitors, and/or control CMOS circuits) and the BS pads (e.g., the DD pad-via structure 310), or a combination thereof. When the first device 300 is stacked under/below another device, the BS DD RDL layers 320, The BS DD RDL-TSV structure 322/324, the DD pad-via structures 310, or a combination thereof can connect the active circuitry 340 and/or a flow through signal (e.g., a signal from a device stacked below the first device 300) to the stacked/upper device.

Like the joint 316, each of the lateral portion 322 and the vertical portion 324 can be connected to each other through a RDL integral joint 326. As described above, the RDL integral joint 326 can have consistency in the material and be integral (e.g., without structural divisions/separations) across the lateral portion 322 and the vertical portion 324. The RDL integral joint 326 can be integral and consistent as a result of forming the lateral portion 322 and the vertical portion 324 through one continuous deposition step (e.g., the DD manufacturing process).

In some embodiments, the first device 300 can include a frontside RDL 332 located closer to or on the FS 306 than the BS 304. For example, the FS RDL 332 can be located opposite the DD pad-via structures 310, the BS DD RDL 320, the BS DD RDL-TSV structures 322/324, or a combination thereof and across the core 308 and/or the active circuitry 340. The FS RDL 332 can be configured to route electrical signals to/from the active circuitry 340, the BS DD RDL 320, or both and or through the FS 306 (e.g., pads on the FS 306). The FS RDL 332 can include one or more layers 336 that each include (1) lateral extensions 334 for routing electrical signals along lateral directions, (2) front vertical portions 338 for routing electrical signals along vertical directions and/or between the layers 336, or a combination thereof. When the first device 300 is stacked on top of another device, the FS RDL 332 can connect the active circuitry 340 and/or a flow through signal (e.g., a signal from a device stacked over the first device 300) to the stacked/lower device.

The various layers, such as for the FS RDL 332, the BS DD RDL, the BS DD RDL-TSV structures 322/324, and/or the DD pad-via structures 310, can be defined or separated using oxide layers (e.g., inter-level dielectric (ILD), such as SiO). Using the BS layers for illustrative purposes, the layering oxide layers can include a pad layer, a via layer, and a RDL layer. For example, the pad layer can include the ILD having the pad portion 312 embedded therein. The via layer can include the ILD adjacent to or below the pad layer and having the via portion 314 embedded therein. The RDL layer can include the ILD adjacent to or below the via layer and having the BS DD RDL 320 (e.g., the lateral portion 322 and/or a portion of the vertical portion 324) embedded therein. As described in detail below, the DD manufacturing process for the DD pad-via structure 310 can include shaping the pad and via layers to form a continuous depression. Subsequently, the DD pad-via structure 310 can be formed by depositing the conductive material into the continuous depression.

In some embodiments, the various layers can be separated by a protection layer. Using the BS layers for illustrative purposes, the first device 300 can include BS protection layers (e.g., SiCN) disposed over or between the oxide layers. The BS protection layers or similar liners may be disposed in the depressions prior to depositing the electrically conductive material. Accordingly, the BS protection layers or similar liners can persist as a separating layer between the oxide layers and the conductive material and prevent diffusion of the conductive material into the oxide layers.

FIG. 3B is a cross-sectional view of the first example device 300 connected to a stacked device 352 in accordance with an embodiment of the present technology. FIG. 3B can illustrate a portion of the stacked device 352 (e.g., a portion below active circuitry therein) and a portion of a first assembly 350 having the stacked device 352 attached over the first example device 300. The first assembly 350 can include a set of stacked semiconductor wafers or a corresponding set of stacked semiconductor chips.

For the example illustrated in FIG. 3B, the BS 304 of the first device 300 can be attached to a top-device FS 356. In some embodiments, the first assembly 350 can have the stacked device 352 and the first device 300 directly bonded to each other, such as without any adhesives or solder. For example, the pad portions 312 of the first device 300 can directly contact and be bonded to (e.g., through diffusion bonding) top pads 354 of the stacked device 352.

The first assembly 350 can include any number of stacked devices. In some embodiments, the first assembly 350 can include two or more (e.g., four, eight, twelve, sixteen, or more) memory devices, such as DRAM or Flash devices that have corresponding storage unit/cell circuits in the active circuitry. The assembly 350 can further include an interface device configured to provide interface or control functions for the stacked devices (e.g., the other memory devices). In some embodiments, the first device 300 can be a core DRAM device, and the top-device 352 can be a top DRAM device.

FIG. 3C is a waterfall diagram 360 for a first stacked assembly (e.g., the stacked assembly 350 of FIG. 3B) in accordance with an embodiment of the present technology. As described above, the stacked assembly can have any number of devices 362 stacked/bonded over each other. For the example illustrated in FIG. 3C, the stacked assembly can include eight (devices 0-7) semiconductor memory devices 362 or chips.

For each of the devices 362, the waterfall diagram 360 can illustrate the IO circuits (e.g., the input/output circuit 160) and the data storage circuits (shown using a circle) therein. The BS DD RDL 320 of FIG. 3A can be illustrated using the top bars (having wider ‘/’ fill). The FS RDL 332 can be illustrated using the bar (having ‘x’ fill) below the data storage circuits. As shown in FIG. 3C, the BS DD RDL 320 and the FS RDL 332 can extend laterally past the data storage circuits, thereby allowing lateral displacement of select connections (e.g., power and/or pass-through data/content signals). The direct bond between the adjacent devices is illustrated using a vertical bar (having wider ‘\’ fill).

The stacked assembly can have communication channels 364 that allow access to each of the devices 362. In other words, the communication channels 364 can allow each of the devices 362 to interact with circuits external to the stacked assembly. In some embodiments, the stacked assembly can include at least one channel (e.g., a connected signal path) dedicated to each of the devices 362. The communication channels 364 can be available at a bottom surface of the stacked assembly. Accordingly, when the stacked assembly is mounted over a printed circuit board (PCB), another semiconductor device, an interposer, or the like, the communication channels 364 can electrically couple the stacked devices 362 to other circuits on the PCB, the external semiconductor device, the interposer, or the like.

The waterfall diagram 360 can illustrate the communication channels 364 or the electrical path that extend between and/or through the stacked devices 362. In some embodiments, a cascading path 376 can provide a communicative path to/from a top device 372 (e.g., device 7). The cascading path 376 for the top device 372 can be accessible for external interface through a first peripheral channel 374 (e.g., channel 7). When the channels are available across a common surface, the locations of the channels require separation across lateral directions. The corresponding lateral signal routing can be provided using the BS DD RDL 320, the FS RDL 332, or a combination thereof in each device. For example, for the cascading path 376, the IO circuit (e.g., the input/output circuit 160) local to the top device 372 can be connected to the DD RDL 320 of the device (device 6) directly underneath, and the DD RDL 320 can route the connection laterally across one channel. The cascading path 376 can similarly shift one lateral channel/location across each successive stacked device. Accordingly, the cascading path 376 for the top device 372 of an eight-device stack can have seven lateral shifts that correspond to seven devices underneath the top device 372. The interface for a bottom die 382 of the stack can be implemented through an opposite peripheral channel 384.

In some embodiments, the first assembly 350 of FIG. 3B can correspond to an offset bond design. As illustrated in the waterfall diagram 360, the offset bond design can have the local IO circuit output directly to the opposite peripheral location. The device underneath can have the lateral portions 322 of FIG. 3A therein configured to offset the connection and route along a lateral direction to a next location within a set of designated interface locations (e.g., predetermined physical locations for the channels on the bottom surface of the stack). The offset bond design can use the lateral portions 322 and/or the lateral extensions 334 of FIG. 3A of the FS RDL 332 of FIG. 3A to laterally offset the power connection, the data/content signals, or both.

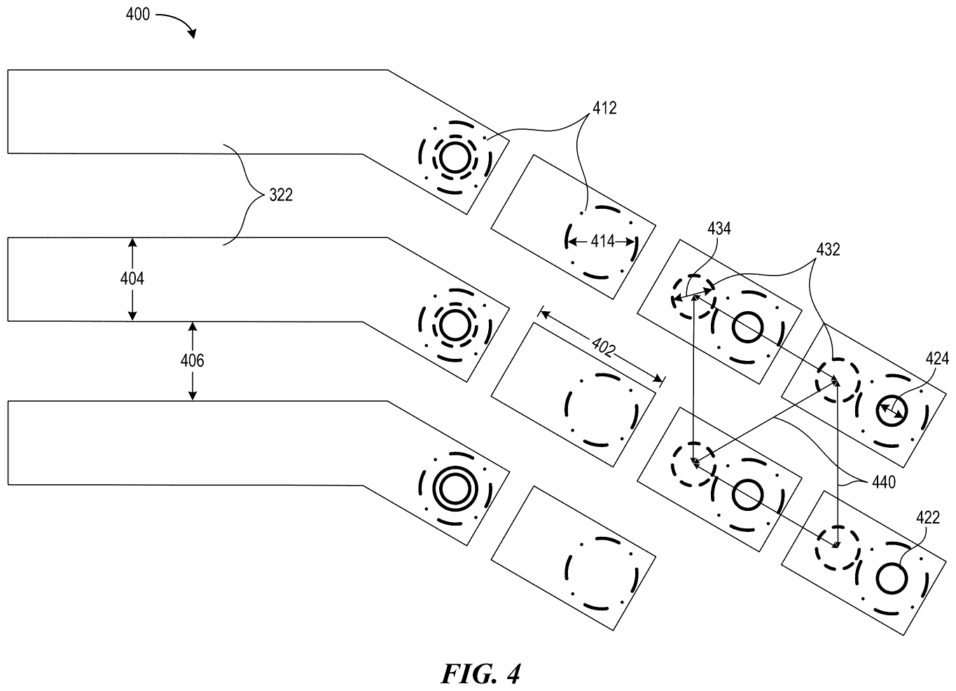

FIG. 4 is a plan view 400 of a redistribution layer (e.g., the BS DD RDL 320 of FIG. 3A) associated with the BS connection mechanism (e.g., the BS connection mechanism 302 of FIG. 3A) in accordance with an embodiment of the present technology. The plan view 400 can represent a portion of a lateral connection pattern.

The lateral portions 322 can have a width 402 and a length 404. In one or more embodiments, the width 402 can be 3-10 μm, and the length 404 can be 1-5 μm. The lateral portions 322 can be separated from each other along one or more lateral directions by a corresponding separation distance 406. In one or more embodiments, the separation distance 406 can be 1-5 μm.

FIG. 4 can further illustrate the lateral portions 322 with various vertical connections above and below represented with circular footprints. For example, the plan view 400 can show bond pad coverage portions 412 (shown using outlines with alternating dashes and dots) that correspond to areas of the lateral portions 322 that are directly under or overlapped by the pad portions 312. In other words, the bond pad coverage portions 412 can indicate the locations of the pad portions 312 and the corresponding external connections relative to the lateral portions 322. Accordingly, the bond pad coverage portions 412 can have dimensions (e.g., radius/diameter) that correspond to bond pad dimensions 414. In some embodiments, the bond pad dimensions 414 can be 1-5 μm.

Similarly, the plan view 400 can show the locations on the lateral portions 322 that connect (e.g., overlap/underlap) with various connections, such as the via portion 314 of FIG. 3A, the vertical portion 324 of FIG. 3A. For example, the plan view 400 can show locations for top via junction 422 (shown using outlines with continuous lines) and/or TSV junction 432 (shown using outlines with dashes). The top via junction 422 can represent the areas of the lateral portions 322 having direct contact with the via portions 314 of the DD pad-via structures 310 above. The TSV junction 432 can represent the area of the lateral portions 322 having direct contact with the vertical portion 324 (e.g., the TSV integrally connected to the lateral portions 322). In other words, the top via junctions 422 and the TSV junctions 432 can represent the footprint of the vertical structures along with the location and size of the connecting portions. Accordingly, the top via junctions 422 and the c have dimensions (e.g., radius/diameter) that correspond to the dimensions of the vertical connecting structures, such as for a top via dimension 424 corresponding to the via portion 314 and a TSV junction dimension 434 corresponding to the vertical portion 324/the integral joint 326 of FIG. 3A. In some embodiments, the top via dimension 424 can be 0.3-3 μm, and the TSV junction dimension 434 can be 0.5-4 μm.

Further, the plan view 400 can illustrate other design rules for the BS connection mechanism 302. For example, the plan view 400 can illustrate a TSV pitch dimension 440 showing the separation distance between the vertical portions 324 of the BS DD RDL 320. In some embodiments, the TSV pitch dimension 440 can be 1-10 μm.

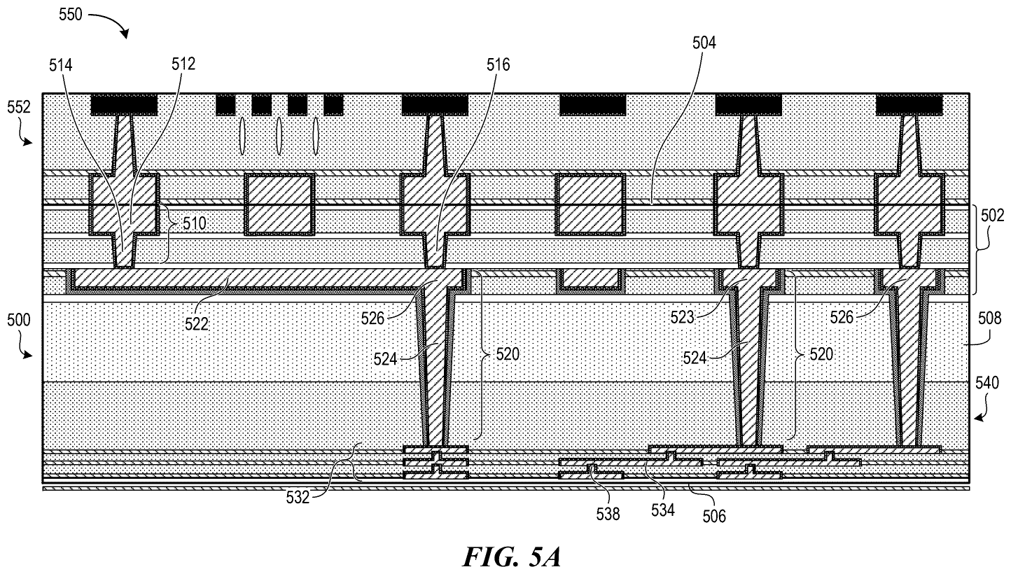

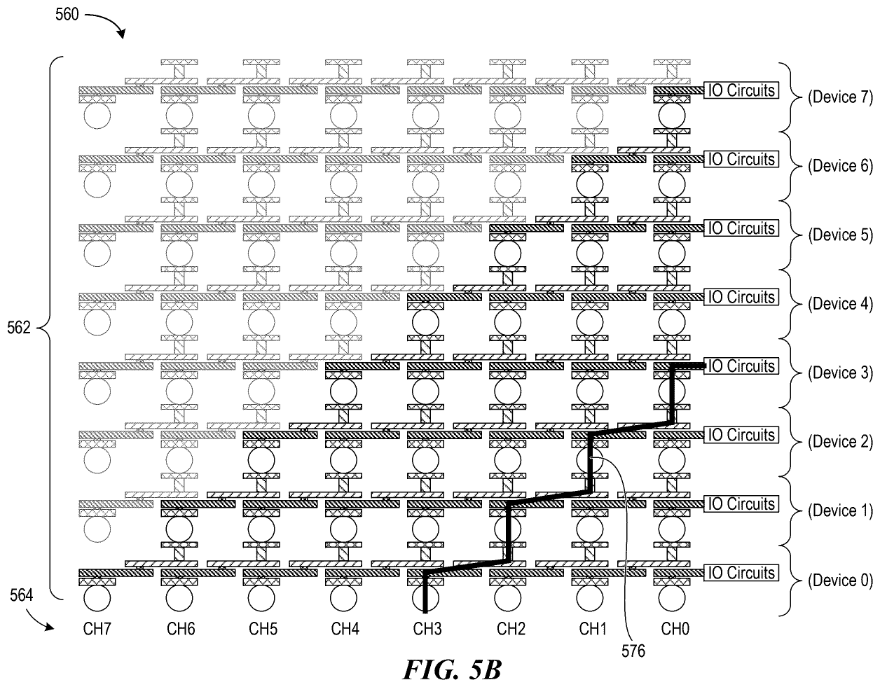

FIG. 5A is a cross-sectional view of a second assembly 550 having a second BS connection mechanism 502 connected to a stacked device 552 in accordance with an embodiment of the present technology. The second assembly 550 can include a second device 500. The second device 500 and the stacked device 552 can each include semiconductor wafers, semiconductor chips, or the like that are stacked or attached over each other. In some embodiments, the second assembly 550 can include the stacked device 552 and the second device 500 can be directly attached (e.g., through diffusion bonding of corresponding pads) to each other.

For illustrative purposes, FIG. 5A can correspond to a portion of the directly bonded wafers representative of a memory device (e.g., the apparatus 100 of FIG. 1, such as a DRAM). The second assembly 550 and the second device 500 can be similar to the first assembly 350 of FIG. 3B and the first device 300 of FIG. 3A, respectively. For example, the second device 500 can have a BS 504 and a FS 506 surrounding or defining opposite sides of a core 508 (e.g., semiconductor substrate material, such as Si). The FS 506 can include active circuitry 540 that implement functions, computations, and/or storage targeted for the device 500. The stacked device 552 can be attached over the second example device 500, and the BS connection mechanism 502 of the second device 500 can be configured to route signals, power, and/or ground connections to/from the stacked device 552. The BS connection mechanism 502 can have one or more layers that each have vertical and lateral portions integrally connected (e.g., as a result of the DD process) to each other.

Similar to the BS connection mechanism 302 of FIG. 3A, the BS connection mechanism 502 can include DD pad-via structures 510 having pad portions 512 and via portions 514 attached to each other through integral joints 516. The pad portions 512 of the second device 500 can be directly attached or bonded to corresponding pads of the stacked device 552. The BS connection mechanism 502 can also include a BS DD RDL 520 having lateral portions 522 and/or pad portions 523 (e.g., an internal landing pad configured to facilitate connection between layers without laterally routing the signal) attached to vertical portions 524 (e.g., TSVs) through RDL integral joints 526. The integral joints 516 and 526 can have consistency in the material and be integral (e.g., without structural divisions/separations) across the conjoining portions. The integral joints 516 and 526 can be integral and consistent as a result of forming the conjoined portions through one continuous deposition step (e.g., the DD manufacturing process).

The second device 500 can include a FS RDL 532 located closer to or on the FS 506 than the BS 504, such as opposite the DD pad-via structures 510, the BS DD RDL 520, or a combination thereof and across the core 508 and/or the active circuitry 540. The FS RDL 532 can be configured to route electrical signals to/from the active circuitry 540, the BS DD RDL 520, or both and or through the FS 506 (e.g., pads on the FS 506). The FS RDL 532 can include one or more layers that each include (1) lateral extensions 534 for routing electrical signals along lateral directions, (2) front vertical portions 538 for routing electrical signals along vertical directions and/or between the layers, or a combination thereof. When the second device 500 is stacked on top of another device, the FS RDL 532 can connect the active circuitry 340 and/or a flow through signal (e.g., a signal from a device stacked over the second device 500) to the stacked/lower device.

The second device 500 and/or the stacked device 552 can include oxide layers (e.g., ILD, such as SiO) and/or protection layers (e.g., SiCN) between layers, structures, or the like. For example, the oxide layers can surround the conductive portions and fill the body of each layer. The protection layers can be disposed between and separate the oxide layers. Additionally or alternatively, the protection layers can be disposed between the integral structure and the oxide material (e.g. covering the surface of depression used to collect the deposited conductive material).

In contrast to the offset bond design or the first device 300 that can use the BS DD RDL 320 and/or the FS RDL 332 for data/content signals, the second device 500 can use one of the RDLs to route the signals laterally. For example, the second device 500 can have the BS DD RDL 520 configured to laterally route power connections and limit the signal connections to vertical paths. In other words, for a given data/content signal, the corresponding via portion 514 and the vertical portion 524 can be aligned along a vertical line. The FS RDL 532 of the second device 500 can include the lateral extensions 534 configured to laterally route the data/content signals. The second device 500 can correspond to a stacked bond design. In contrast to the content/data signals, the BS DD RDL 520 can provide a thicker or a wider connection path through the BS DD RDL 520, thereby facilitating the flow of higher currents and power (e.g., power supply or source voltage). In addition, the seamless integral joints in the BS DD RDL 520 can further lower the resistance in the path and provide higher density for the overall connection paths while reducing the manufacturing costs required to achieve such improvements.

FIG. 5B is a waterfall diagram 560 for the second assembly 550 of 5A in accordance with an embodiment of the present technology. Similar to the stacked assembly and the corresponding waterfall diagram 360 of FIG. 3C, the waterfall diagram 560 can illustrate a number of devices 562 and a matching number of communication channels 564 that each uniquely facilitate one of the devices 562. For the example illustrated in FIG. 5B, the stacked assembly can include eight (devices 0-7) semiconductor memory devices 562 or chips with eight communication channels 564 (channels 0-7). For the stacked bond design and/or the second assembly 550 of FIG. A, the waterfall diagram 560 can illustrate cascade paths 576 that utilize the FS RDL 532 of FIG. 5A to laterally route data/content signals.

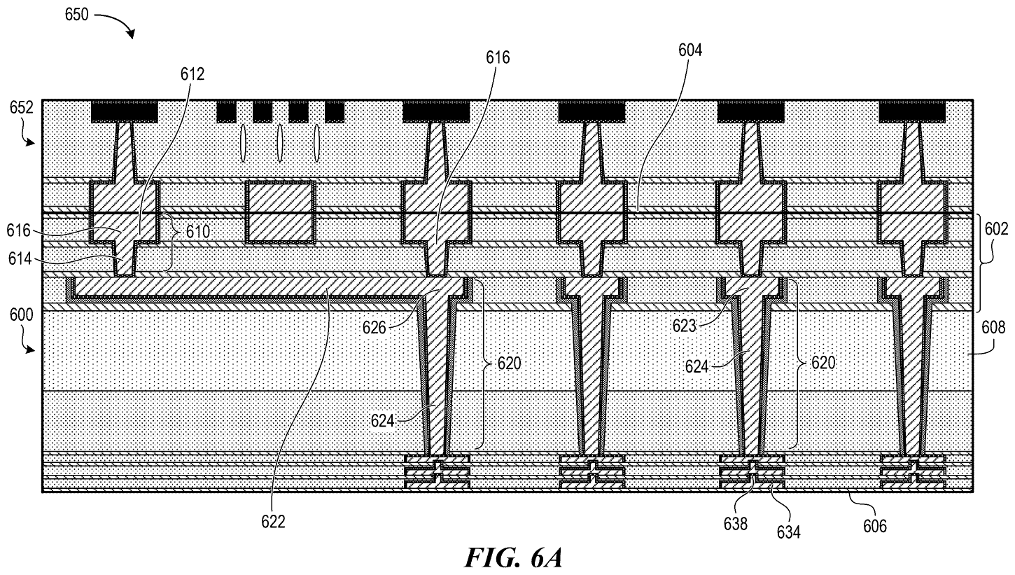

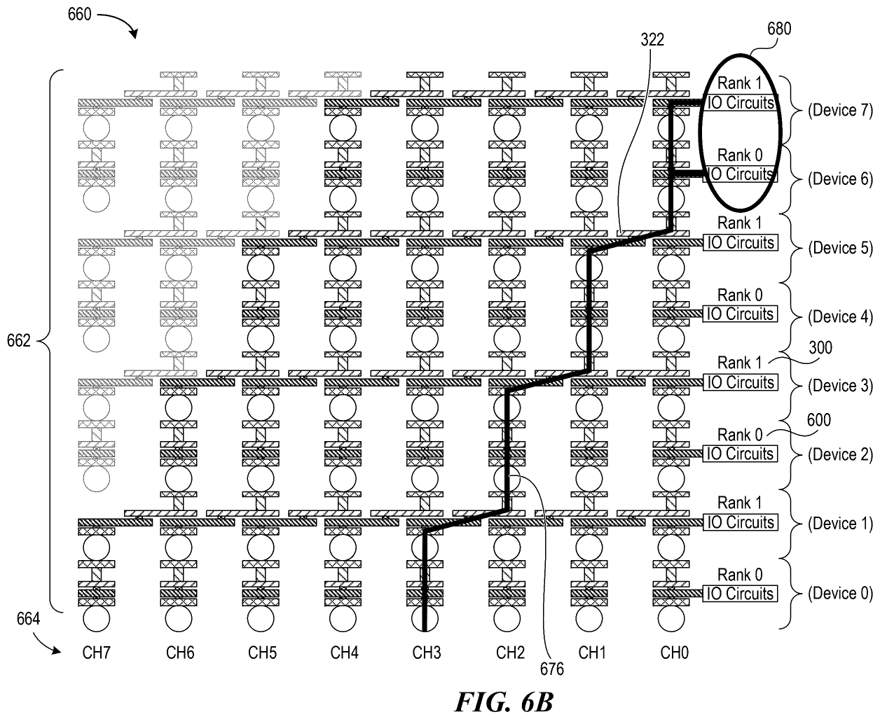

FIG. 6A is a cross-sectional view of a third assembly 650 having a third BS connection mechanism 602 connected to a stacked device 652 in accordance with an embodiment of the present technology. The third assembly 650 can include a third device 600. The third device 600 and the stacked device 652 can each include semiconductor wafers, semiconductor chips, or the like that are stacked or attached over each other. In some embodiments, the third assembly 650 can include the stacked device 652 and the third device 600 can be directly attached (e.g., through diffusion bonding of corresponding pads) to each other.

For illustrative purposes, FIG. 6A can correspond to a portion of the directly bonded wafers representative of a memory device (e.g., the apparatus 100 of FIG. 1, such as a DRAM). The third assembly 650 and the third device 600 can be similar to the first assembly 350 of FIG. 3B and the second assembly 550 of FIG. 5B, the first device 300 of FIG. 3A and the second device 500 of FIG. 5A, respectively. For example, the third device 600 can have a BS 604 and a FS 606 surrounding or defining opposite sides of a core 608 (e.g., semiconductor substrate material, such as Si). The FS 606 can include active circuitry 640 that implement functions, computations, and/or storage targeted for the device 600. The stacked device 652 can be attached over the third device 600, and the BS connection mechanism 602 of the third device 600 can be configured to route signals, power, and/or ground connections to/from the stacked device 652. The BS connection mechanism 602 can have one or more layers that each have vertical and lateral portions integrally connected (e.g., as a result of the DD process) to each other.

Similar to the BS connection mechanism 302 of FIG. 3A and the BS connection mechanism 502 of FIG. 5A, the BS connection mechanism 602 can include DD pad-via structures 610 having pad portions 612 and via portions 614 attached to each other through integral joints 616. The pad portions 612 of the third device 600 can be directly attached or bonded to corresponding pads of the stacked device 652. The BS connection mechanism 602 can also include a BS DD RDL 620 having lateral portions 622 and/or pad portions 623 (e.g., an internal landing pad configured to facilitate connection between layers without laterally routing the signal) attached to vertical portions 624 (e.g., TSVs) through RDL integral joints 626. The integral joints 616 and 626 can have consistency in the material and be integral (e.g., without structural divisions/separations) across the conjoining portions. The integral joints 616 and 626 can be integral and consistent as a result of forming the conjoined portions through one continuous deposition step (e.g., the DD manufacturing process).

The third device 600 can include a FS RDL 632 located closer to or on the FS 606 than the BS 604, such as opposite the DD pad-via structures 610, the BS DD RDL 620, or a combination thereof and across the core 608 and/or the active circuitry 640. The FS RDL 632 can be configured to route electrical signals to/from the active circuitry 640, the BS DD RDL 620, or both and or through the FS 606 (e.g., pads on the FS 606). The FS RDL 632 can include one or more layers that each include (1) FS pads 634 for connecting to the previous layer, (2) front vertical portions 638 for routing electrical signals along vertical directions and/or between the layers, or a combination thereof. When the third device 600 is stacked on top of another device, the FS RDL 632 can connect the active circuitry 340 and/or a flow through signal (e.g., a signal from a device stacked over the third device 600) to the stacked/lower device.

The third device 600 and/or the stacked device 652 can include oxide layers (e.g., ILD, such as SiO) and/or protection layers (e.g., SiCN) between layers, structures, or the like. For example, the oxide layers can surround the conductive portions and fill the body of each layer. The protection layers can be disposed between and separate the oxide layers. Additionally or alternatively, the protection layers can be disposed between the integral structure and the oxide material (e.g. covering the surface of depression used to collect the deposited conductive material).

In contrast to the offset bond design and the first device 300 that can use both the BS DD RDL 320 and the FS RDL 332, the third device 600 can have the BS DD RDL 620 configured to laterally route power connections and vertically route signal connections. In other words, the via portion 614 and the vertical portion 624 configured to communicate the same non-power or data/content signal can be aligned along a vertical line. In contrast to the second device 500 and the stacked bond that use the FS RDL 532 of FIG. 2A to laterally route the data/content signals, the FS RDL 632 of the third device 600 can be configured to vertically route the data/content signals. Accordingly, the third device 600 can have its data/content signal pads aligned along vertical lines with the device above or below. In other words, the third device 600 can be configured to pass the pass-through data/content signals along vertical directions (e.g., without lateral displacement). The third device 600 can correspond to a multi-rank stacked bond design.

FIG. 6B is a waterfall diagram 660 for the third assembly 650 in accordance with an embodiment of the present technology. Similar to the stacked assemblies and the corresponding waterfall diagrams described above, the waterfall diagram 660 can illustrate a number of devices 662 and a matching number of communication channels 664 that each uniquely facilitate one of the devices 662. For the example illustrated in FIG. 6B, the stacked assembly can include eight (devices 0-7) semiconductor memory devices 662 or chips with eight communication channels 664 (channels 0-7).

For the multi-rank stack and/or the third assembly 650 of FIG. A, the overall assembly (e.g., the third assembly 650) can have one or more groupings or rank sets of devices. In other words, each grouping of devices can include devices corresponding multiple communication ranks (e.g., memory location organization scheme). For the example illustrated in FIG. 6B, the third assembly 650 can correspond to a dual-rank stack and include rank sets 680 that include two types of devices that correspond to two ranks (e.g., rank 0 and rank 1).

The multi-ranked stack can include one device (e.g., top device in the rank grouping) configured to laterally route data/content signals, and the remaining devices can be configured to communicate the pass-through signals vertically without lateral displacement. In other words, the remaining devices can correspond to the multi-rank stacked bond design described above in FIG. 6A. Accordingly, the corresponding cascade paths 676 can be routed laterally along a designated device within the rank sets 680 and extend vertically across other devices within the rank sets 680.

The laterally routing devices can correspond to the first device 300 of FIG. 3A or the second device 500 of FIG. 5A and utilize the respective BS DD RDL 320 of FIG. 3A and/or the FS RDL 332 of FIG. 3A or the BS DD RDL 520 of FIG. 5A to laterally route the data/content signals. The vertically routing devices can correspond to the third device 600.

Using the example illustrated by the waterfall diagram 660, the dual-rank stacked bond design can have the first device 300 stacked over the third device 600 within each of the rank sets 680. Accordingly, each of the rank sets 680 can utilize the BS DD RDL 320 of FIG. 3A and/or the FS RDL 332 to laterally displace a selected set of signals (e.g., pass-through data/content signals) by a predetermined number of interface locations. The third device 600 can route the selected set of signals along a vertical direction. Accordingly, each of the rank sets 680 can displace the selected set of signals by the predetermined number (e.g., one or two) of interface locations.

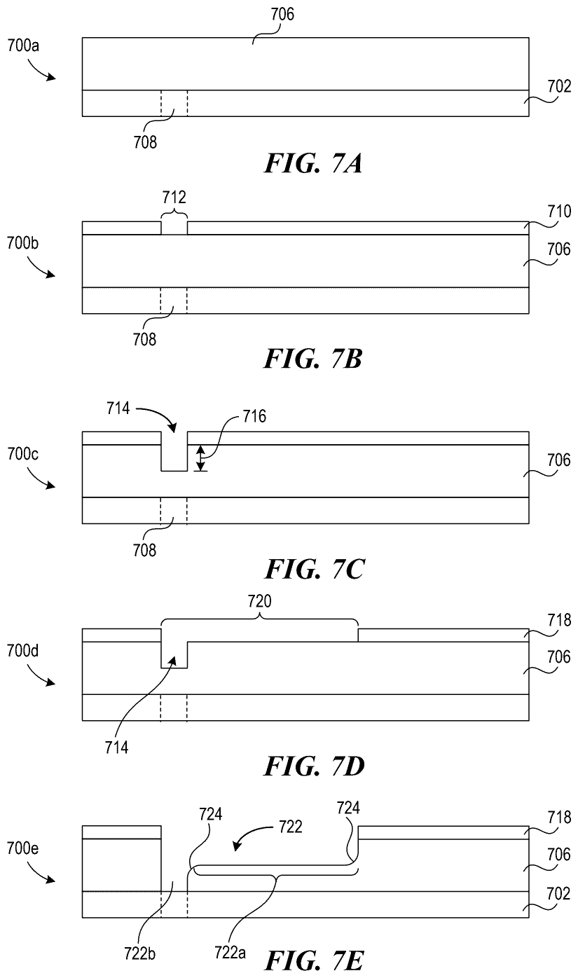

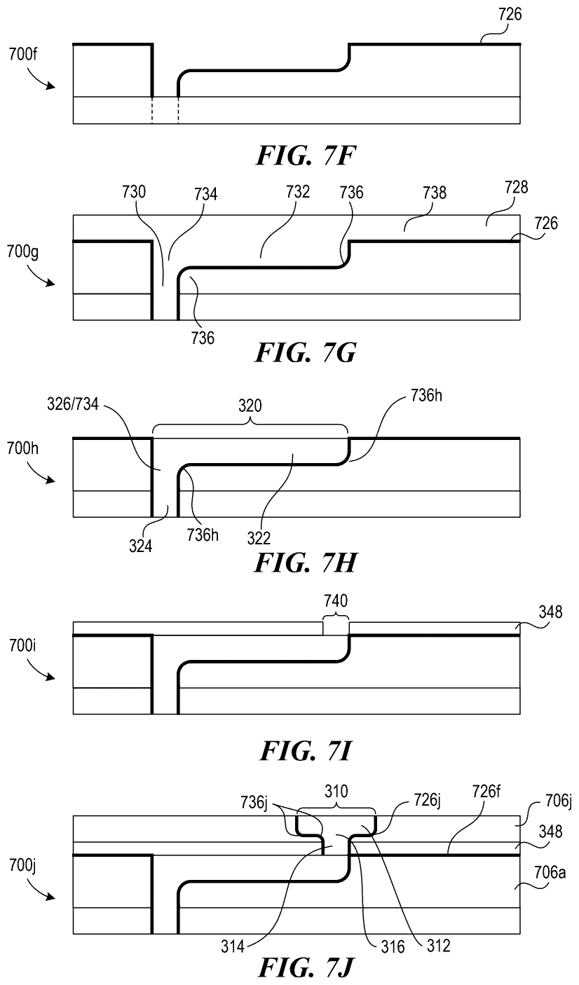

FIGS. 7A-7J are illustrations of various stages of an example manufacturing process in accordance with an embodiment of the present technology. The example manufacturing process can be for forming one or more of the devices (e.g., the first device 300 of FIG. 3A, the second device 500 of FIG. 5A, and/or the third device 600 of FIG. 6A). For example, the illustrated manufacturing process can show the formation of the BS connection mechanism.

FIG. 7A can illustrate an initial structure 700a having a semiconductor substrate 702 (e.g., a Si wafer) with a dielectric layer 706 (e.g., the ILD, such as the SiO) formed thereon. The semiconductor substrate 702 can have the active circuitry (e.g., the active circuitry 340/540/640 of corresponding FIGS) formed thereon, such as using dopants. The dielectric layer 706 can be formed on an opposite side of the active circuitry. Accordingly, the dielectric layer 706 can correspond to a back portion or the BS of the subsequently resulting device.

In some embodiments, the semiconductor substrate 702 can have one or more through silicon cavities 708. The through silicon cavities 708 can correspond to etched depressions that may be subsequently occupied by electrically conductive material (e.g., the vertical portions of the BS DD RDLs). Accordingly, the through silicon cavities 708 can extend toward one or more electrical components or connections amongst the active circuitry on the FS of the semiconductor substrate 702. Alternatively, the semiconductor substrate 702 can have the one or more through silicon cavities 708 already filled with the electrically conductive material (e.g., copper).

FIG. 7B can illustrate a structure 700b following a masking process. The structure 700b can have a patterning layer 710 (e.g., a mask, such as a photoresist) formed over the initial structure 700a of FIG. 7A. The patterning layer 710 can include one or more via openings 712 that expose the corresponding portion(s) of the dielectric layer 706 underneath. The via openings 712 can correspond to the vertical portions (e.g., the vertical portion 324 of FIG. 3A) of the BS DD RDL structures described above. In some embodiments, the structure 700b can result from depositing or laminating an optical mask over the dielectric layer 706 and then removing portions thereof (e.g., using light) to form the via openings 712. In some embodiments, one or more of the via openings 712 can be directly over the through silicon cavities 708.

FIG. 7C can illustrate a structure 700c following a first etching process. The structure 700c can have one or more partial vias 714 formed through the corresponding via openings 712 of FIG. 7B. The partial vias 714 can extend partially through a thickness of the dielectric layer 706. The partial vias 714 can be formed by removing (e.g., using chemical etchants or laser) portions of the dielectric layer 706 through the via openings 712. The removal process can be controlled, such as by controlling the exposure to the removal mechanism, the amount or intensity of the removal mechanism, or a combination thereof, so that the partial vias 714 have a partial depth 716 that is less than the thickness of the dielectric layer 706. Accordingly, the semiconductor substrate 702 of FIG. 7B and/or the through silicon cavities 708 can be covered by the remaining portions of the dielectric layer 706.

FIG. 7D can illustrate a structure 700d following a mask adjustment process. The structure 700d can have an updated patterning layer 718 (e.g., a mask, such as a photoresist) over the structure 700c of FIG. 7D. The updated patterning layer 718 can be formed by adjusting the patterning layer 710 of FIG. 7B. For example, the updated patterning layer 718 can have an RDL opening 720 that may be formed by enlarging one or more of the via openings 712. In some embodiments, the updated patterning layer 718 can be formed by removing additional portions of the patterning layer 710, such as using the same removal mechanism used to form the initial via openings 712. The updated patterning layer 718 can be formed at locations and with shapes that correspond to the lateral portions (e.g., the lateral portion 322 of FIG. 3A) of the BS DD RDL.

FIG. 7E can illustrate a structure 700e following a second etching process. The structure 700e can have one or more patterned depressions 722. The patterned depressions 722 can be formed by removing the dielectric layer 706 through the updated patterning layer 718 using the same removal mechanism as the first etching process.

The patterned depressions 722 can each have a lateral portion 722a and a vertical portion 722b. The lateral portions 722a can correspond to partial depressions in the dielectric layer 706 formed by removing portions of the dielectric layer 706 through the RDL opening 720. The vertical portions 722b can be extensions of the partial vias 714 FIG. 7D and expose the semiconductor substrate 702. In some embodiments, the etching process can leave rounded corners 724 in the dielectric layer 706. Given the continued opening between the vertical portions 722b and the lateral portions 722a, the patterned depressions 722 can have the rounded corners 724 between the corresponding portions.

FIG. 7F can illustrate a structure 700f following a preparation process. The structure 700f can have one or more initial layers 726 formed over the structure 700e of FIG. 7E. For example, the initial layers 726 can include a diffusion barrier (e.g., a tantalum (Ta) based barrier), a seed layer (e.g., initial layer of copper (Cu)), or a combination thereof. The initial layers 726 may be formed using a depositing process, such as a physical vapor deposition (PVD).

FIG. 7G can illustrate a structure 700g following a conductor depositing process, such as a metal depositing or an electroplating process. The structure 700g can have a metallic material, such as Cu, deposited over the structure 700f of FIG. 7F to form deposited structure 728. The deposited structure 728 can be formed based on the deposited material attaching to and forming over the one or more initial layers 726, such as the seed layer.

The deposited structure 728 can have portions that correspond to the shape/portions of the structure 700f. For example, the deposited structure 728 can include one or more vertical extensions 730 that extend along vertical directions (e.g., toward the core 308 of FIG. 3A) and one or more lateral extensions 732 integrally joined by corresponding integral joint(s) 734 (e.g., the integral joints 326 of FIG. 3A or the like described above). The deposited structure 728 can have an excess portion 738 over one or more portions of the structure 700f.

In some embodiments, the deposited structure 728 can have rounded corners 736 including at the integral joints 734. The rounded corners 736 at the integral joints 734 can correspond to the shape of the structure 700f at the corresponding portions. For example, the rounded corners 736 may be formed as a result of the DD process used to shape the structure 700f, thus shaping the deposited structure 728.

FIG. 7H can illustrate a structure 700h following an excess removal process, such as a polishing process, an etching process, or a combination thereof, to remove the excess portion 738 of FIG. 7G. For example, the excess removal process can include a chemical-mechanical planarization (CMP) process to form the BS DD RDL 320 from the deposited structure 728 of FIG. 7G. Accordingly, the vertical extension 730 of FIG. 7G can correspond to the vertical portion 324, the lateral extension 732 of FIG. 7G can correspond to the lateral portion 322, and the joint 734 of FIG. 7G can correspond to the integral joint 326. Accordingly, the integral joint 326 can include the rounded corners 736. Moreover, the removal of the excess portion 738 can expose portions of the initial layer 726 of FIG. 7F (e.g., the barrier layer located between or adjacent to the BS DD RDL 320).

FIGS. 7I and 7J can correspond to steps for forming the BS DD pad-via structures 310 of FIG. 3A over the BS DD RDL 320 of FIG. 7H. FIG. 7I can illustrate a structure 700i following a capping layer depositing process. The deposited capping layer can correspond to the BS protection layer 348 or other protection (e.g., etch stop) layers. In some embodiments, the capping layer can be deposited through lamination, lithography, chemical and/or physical deposition, or the like. Moreover, the deposited capping layer can be shaped, such as to form openings. The formed openings can include connector openings 740 that expose corresponding top portions of the BS DD RDL 320.

FIG. 7J can illustrate a structure 700j following one or more manufacturing processes for the BS DD pad-via structures 310. The manufacturing processes for the BS DD pad-via structures 310 can correspond to those of the BS DD RDL 320 of FIG. 7H. For example, the manufacturing processes can parallel the steps described above for FIGS. 7C-7H.

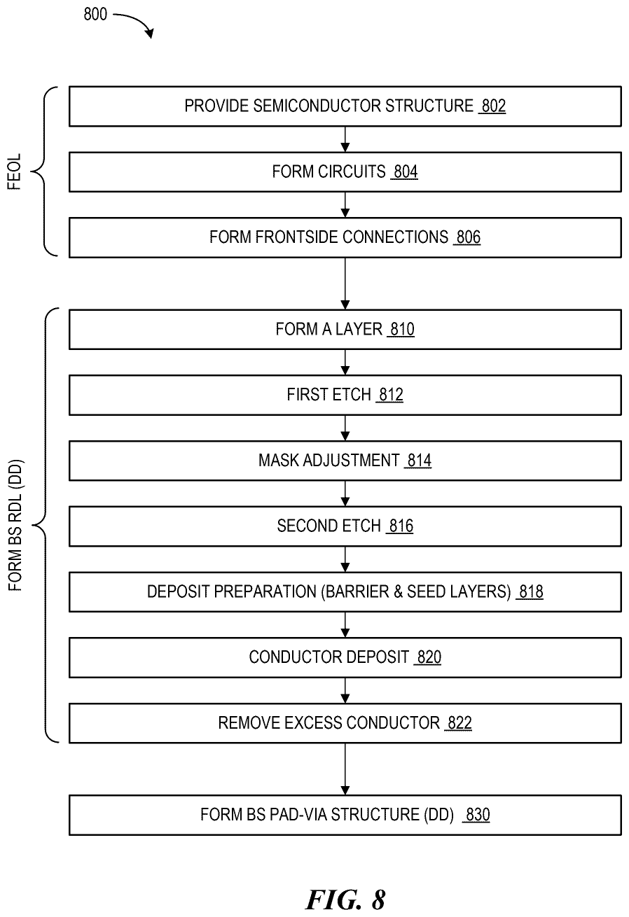

FIG. 8 is a flow diagram illustrating an example method 800 of manufacturing a semiconductor device (e.g., the apparatus 100 of FIG. 1, the first/second/third device described above, and/or the corresponding assemblies described above) with a BS routing mechanism in accordance with an embodiment of the present technology. For example, the example method 800 can correspond to forming the BS DD pad-via structures 310 of FIG. 3A, the BS DD RDL 320 of FIG. 3A, the corresponding structures for the second device 500 of FIG. 5A, and/or the corresponding structures for the third device 600 of FIG. 6A. The example method 800 can correspond to the process described above and the structures illustrated in one or more of FIGS. 7A-7J.

At block 802, the method 800 can include providing a semiconductor structure, such as a semiconductor wafer or substrate corresponding to the core 308 of FIG. 3A and/or the semiconductor substrate 702 of FIG. 7A. The semiconductor structure can have an active or a FS and a BS. At block 804, the method 800 can include forming active circuitry (e.g., the active circuitry 340 of FIG. 3A or the corresponding portions of other devices described above) at or nearer to the FS. The active circuitry can be formed by masking, depositing dopants, layering, and/or forming other electrical components on or near the FS. At block 806, the method 800 can further include forming the FS electrical connections, such as the FS RDL 332 of FIG. 3A or the or the corresponding portions of other devices described above. The forming the FS electrical connections can further include forming TSVs (e.g., the TSV using the through silicon cavity 708 of FIG. 7A corresponding to the vertical portion 324 of FIG. 3A or the like) extending vertically through the thickness of the semiconductor, such as by masking, etching, and/or depositing conductive material. The FS electrical connections can be formed by building layers of IDL, forming patterned masks, depositing conductive material according to the predetermined pattern, and/or the like. In some embodiments, blocks 802-806 can correspond to front-end-of-line (FEOL) manufacturing processes.

At block 810, the method 800 can include forming a layer, such as by depositing the IDL, on the BS of the semiconductor structure. Block 810 can correspond to the process described above for forming the initial structure 700a of FIG. 7A. At block 812, the method 800 can include forming a mask, such as described above regarding the structure 700b of FIG. 7B.

At block 812, the method 800 can include implementing a first etching process using the formed mask to partially etch portions of the ILD, such as described above regarding the structure 700c of FIG. 7C. At block 814, the method 800 can include implementing a mask adjustment process corresponding to the structure 700d of FIG. 7D. At block 816, the method 800 can include a second etching process using the adjusted mask, such as described above for structure 700e of FIG. 7D. At block 818, the method 800 can include a preparation process for the patterned ILD in advance of a depositing process. Block 818 can correspond to the process described for the structure 700f of FIG. 7F. Following the preparation, at block 820, the method 800 can include a conductor depositing process corresponding to the structure 700g of FIG. 7G. At block 822, the method 800 can include an excess removal process to shape the deposited conductor, such as described above for the structure 700h of FIG. 7H. In some embodiments, blocks 812-822 can correspond to the DD process, such as used for forming the BS DD RDL 520.

At block 830, the method 800 can include forming a further layer, such as outer-most set of layers including the BS DD pad-via structures 310. The further layer can be formed using one or more processes described above, such as for blocks 810-822. For example, the DD manufacturing process can be utilized to form the IDL having the BS DD pad-via structures 310 included therein. Using the DD manufacturing process for forming the BS DD RDL 520 and/or the BS DD pad-via structures 310 can leverage existing manufacturing processes for forming conventional semiconductor devices. Accordingly, the BS DD RDL 520 and/or the BS DD pad-via structures 310 can provide the additional routing complexity and the signal density without retooling or otherwise significantly altering the manufacturing facilities. Thus, the BS DD RDL 520 and/or the BS DD pad-via structures 310 can provide the additional signal complexity with minimal to no increased manufacturing cost/complexity.

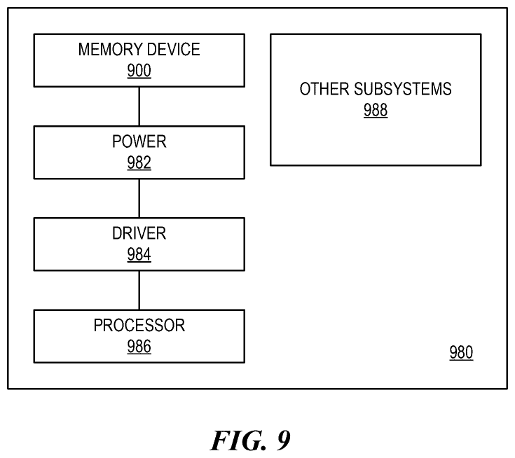

FIG. 9 is a schematic view of a system that includes an apparatus in accordance with embodiments of the present technology. Any one of the foregoing apparatuses (e.g., memory devices) described above with reference to FIGS. 1-8 can be incorporated into any of a myriad of larger and/or more complex systems, a representative example of which is system 980 shown schematically in FIG. 9. The system 980 can include a memory device 900, a power source 982, a driver 984, a processor 986, and/or other subsystems or components 988. The memory device 900 can include features generally similar to those of the apparatus described above with reference to FIGS. 1-8, and can therefore include various features for performing a direct read request from a host device. The resulting system 980 can perform any of a wide variety of functions, such as memory storage, data processing, and/or other suitable functions. Accordingly, representative systems 980 can include, without limitation, hand-held devices (e.g., mobile phones, tablets, digital readers, and digital audio players), computers, vehicles, appliances and other products. Components of the system 980 may be housed in a single unit or distributed over multiple, interconnected units (e.g., through a communications network). The components of the system 980 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-9.

I/we claim:

1. A semiconductor device, comprising:
a semiconductor substrate having a front portion opposite a back portion;
active circuitry formed in or on the semiconductor substrate and located closer to the front portion than the back portion; and
an integral electrical connector overlapping the back portion, the integral electrical connector having a lateral portion and a vertical portion that extends toward the front portion, wherein the lateral and vertical portions are integrally joined with each other with conductive material for the integral electrical connector remaining consistent and uninterrupted across the lateral and vertical portions.

2. The semiconductor device of claim 1, wherein the integral electrical connector includes one or more characteristics resulting from a dual-damascene process used to form the integral electrical connector.

3. The semiconductor device of claim 2, wherein:
the integral electrical connector comprises a backside redistribution layer;
the lateral portion is configured to provide an electrical connection that extends along at least one lateral direction; and
the vertical portion (1) at least partially extends through the semiconductor substrate to the front portion or (2) electrically couples to a through-silicon via that at least partially extends through the semiconductor substrate to the front portion, wherein the vertical portion is configured to provide the electrical connection along a vertical direction and to the active circuitry, the front portion, or a combination thereof.

4. The semiconductor device of claim 3, further comprising:
a front side redistribution layer on the front portion of the semiconductor substrate and opposite the backside redistribution layer, wherein the front side redistribution layer is configured to further extend the electrical connection along the at least one lateral direction.

5. The semiconductor device of claim 3, wherein:
the active circuitry is configured to communicate an internally processed signal with a first external circuit located facing the front portion of the semiconductor substrate; and
the lateral portion of the backside redistribution layer is configured to (1) receive a pass-through signal received from a second external circuit facing the back portion of the semiconductor device and (2) laterally displace the pass-through signal away from the internally processed signal.

6. The semiconductor device of claim 2, wherein:
the integral electrical connector comprises a pad-via structure;
the lateral portion is configured to provide a bonding pad configure to attach to an external pad or connector; and
the vertical portion is narrower than the lateral portion and electrically coupled to (1) a through-silicon via that at least partially extends through the semiconductor substrate to the front portion or (2) a redistribution layer disposed between the back portion and the lateral portion.

7. The semiconductor device of claim 2, wherein the one or more characteristics of the dual-damascene process includes one or more rounded corners at an integral joint between the vertical and lateral portions.

8. The semiconductor device of claim 2, wherein:
the integral electrical connector includes an electrically conductive metallic material; and
the one or more characteristics of the dual-damascene process includes a uniform density in the electrically conductive metallic material across the vertical and lateral portions, including an integral joint between the vertical and lateral portions.

9. The semiconductor device of claim 2, wherein the active circuitry includes memory cells configured to store data.

10. The semiconductor device of claim 9, wherein the semiconductor device comprises a dynamic random-access memory (DRAM).

11. A three-dimensionally integrated semiconductor device, comprising:
a first device including (1) a first active circuitry and (2) a first pad on a bottom surface of the first device and configured to provide an external interface for the first active circuitry; and
a second device attached to and below the first device, the second device having a back portion facing the first device and opposite a front portion, the second device further including:
a second active circuitry,
a second active pad on the front portion and configured to provide an external interface for the second active circuitry,
a second receiving pad located on the back portion and coupled to the first pad, the second receiving pad aligned with the second active pad,
a second pass-through pad located on the front portion and separated from the second active pad along a lateral direction;
a backside redistribution layer disposed between and coupled to the second receiving pad and the second pass-through pad, the backside redistribution layer having a lateral portion integrally joined with a vertical portion,
wherein the lateral portion extend across the lateral direction, and
wherein the vertical portion extends from the lateral portion toward the front portion along a vertical direction for electrically coupling the lateral portion and the second pass-through pad.

12. The three-dimensionally integrated semiconductor device of claim 11, wherein the second active pad comprises a backside pad-via structure that further includes a vertical portion integral with and extending from the second active pad toward the backside redistribution layer for electrically coupling the second active pad to the backside redistribution layer.

13. The three-dimensionally integrated semiconductor device of claim 12, wherein the integral connections between (1) the vertical portion and the vertical portion of the backside pad-via structure and (2) the lateral portion and the vertical portion of the backside redistribution layer are results of forming the backside pad-via structure and the backside redistribution layer, respectively, using corresponding dual damascene processes.

14. The three-dimensionally integrated semiconductor device of claim 11, further comprising:
a through silicon via (TSV) extending at least partially through a semiconductor core and between the back portion and the front portion, the TSV connected to the vertical portion of the backside redistribution layer and configured to electrically couple the lateral portion to the second pass-through pad.

15. The three-dimensionally integrated semiconductor device of claim 11, wherein the vertical portion of the backside redistribution layer is a TSV that extends at least partially through a semiconductor core and between the back portion and the front portion for electrically coupling the lateral portion to the second pass-through pad.

16. The three-dimensionally integrated semiconductor device of claim 11, further comprising:
a frontside redistribution layer disposed between the second active circuitry and a front surface exposing the second active pad and the second pass-through pad,
wherein the frontside redistribution layer extends a first portion of a lateral separation between the second receiving pad and the second pass-through pad, and
wherein the lateral portion of the backside redistribution layer extends a remaining portion of the lateral separation.

17. The three-dimensionally integrated semiconductor device of claim 11, wherein the lateral portion of the backside redistribution layer extends across a lateral separation between the second receiving pad and the second pass-through pad.

18. The three-dimensionally integrated semiconductor device of claim 11, further comprising:
a complementary device disposed between the first device and the second device, the complementary device including:
a complementary receiving pad on a top portion of the complementary device and directly connected to the first pad,
a complementary pass-through pad on a bottom portion of the complementary device and electrically coupled to the complementary receiving pad, the complementary pass-through pad directly connected to the second receiving pad,
a complementary active circuitry, and
a complementary active pad on the bottom portion and configured to provide an external interface for the complementary active circuitry,
wherein the first device, the second device, and the complementary device are memory devices,
wherein the first device is a rank 1 device and the complementary device is a rank 0 device for a first memory rank set,
wherein the second device is a rank 1 device for a second memory rank set,
wherein the complementary receiving pad, the complementary active pad, the first pad, and the second receiving pad are located within a first region on a lateral plane extending parallel to the first, second, and complementary devices, wherein the first region is associated with a first communication channel, and
wherein the second active pad and the second pass-through pad are located within a second region on the lateral plane, wherein the second region is associated with a second communication channel.

19. The three-dimensionally integrated semiconductor device of claim 11, wherein the first pad of the first device is directly bonded with the second receiving pad of the second device.

20. A semiconductor memory device, comprising
a semiconductor substrate having a front portion opposite a back portion;
one or more first backside (BS) dielectric layers on the back portion;
a BS redistribution layer (RDL) structure disposed in the one or more first BS dielectric layers, the BS RDL structure having a laterally-extending portion integrally joined with a vertical portion that extends toward the front portion;
one or more second BS dielectric layers over the one or more first BS dielectric layers;
a pad-via structure disposed in the one or more second BS dielectric layers, the pad-via structure including a pad portion and a vertical portion integral with each other,
wherein the pad portion is configured to receive a pass-through signal from an external device stacked on top of the semiconductor memory device,
wherein the vertical portion extends from the pad portion for electrically routing the pass-through signal to the BS RDL structure;
active circuitry formed in or on the semiconductor substrate and located closer to the front portion than the back portion;
an active pad exposed on a frontside of the semiconductor memory device and configured to provide an external communication interface for the active circuitry, wherein the active pad is aligned with the pad portion along a vertical line;
a pass-through pad exposed on the frontside and electrically coupled to the vertical portion of the BS RDL, wherein the pass-through pad is separated from the active pad along a lateral direction that at least partially corresponds to the laterally-extending portion of the BS RDL structure.
